(19) United States
(12) Patent Application Publication
(10) Pub. No.: US 2011/0292293 A1
(43) Pub. Date: Dec. 1, 2011

(54) SYSTEMS AND METHODS FOR PRODUCING AN ELECTRONIC DISPLAY WITH AN ORGANIZATIONAL COLOR SCHEME AND LOGO

(75) Inventor: Steven Fleming, Valencia, CA (US)

(73) Assignee: Otha Athletic Company, Beverly Hills, CA (US)

(21) Appl. No.: 12/789,346

(22) Filed: May 27, 2010

(51) Int. Cl. H04N 5/44; H05K 13/00; H01J 9/00; H04N 5/64; H04N 9/64

(52) U.S. Cl. 348/714; 348/836; 348/734; 445/24; 29/592.1; 348/E05.128; 348/E09.037; 348/E05.096

(57) ABSTRACT

An example embodiment includes a method of manufacturing an electronic display, where the electronic display is configured to display an image to a user. The method includes providing input circuitry, where the input circuitry receives an input signal and where the input signal is configured to be converted to an image by the electronic display. The method also includes providing display circuitry, where the display circuitry converts the input signal to the image, and receiving an emblem and color scheme from an organization. The method further includes providing a housing. The housing substantially encloses the input circuitry and display circuitry, includes the emblem received from the organization and includes the color scheme received from the organization.

### CROSS-REFERENCE TO RELATED APPLICATIONS

Not applicable.

### BACKGROUND OF THE INVENTION

The television and other electronic video displays have revolutionized the way that people receive information and entertainment. Initially, televisions were bulky and came in one or two design options. Increasingly, however, consumers have been given a wider array of design choices. New technologies, such as high definition, rear screen projection, projectors, liquid crystal displays, plasma have all increased the number of options available to consumers both in the appearance and the quality of the displays.

Nevertheless, one feature in the evolution of the television remains constant, the consumer has very few options to customize the design of the television. The vast majority of televisions are rectangular and display the manufacturer's logo. Furthermore, consumers have very little choice regarding color or other design features. Additionally, organizations may purchase large numbers of televisions and other electronic video displays, such as projectors and computer monitors, but these organizations are stuck without a way to customize the displays unless they are willing to begin producing their own displays, which could end up costing large sums of money. Moreover, many organizations, such as sports teams, have large numbers of fans and these organizations would like to provide merchandise to these fans that would reflect the follower's support of the organization.

In addition, many of the current technologies require a high level of expertise to produce. In many cases, the processes do not become efficient until a large number of devices are produced. That is, the manufacture of a few televisions or a small number of televisions with a particular design would become extremely expensive to produce. Additionally, producing a small number of displays would result in high failure rates, making it nearly impossible to reliable produce a small number of displays while accurately predicting the number that would actually function.

Accordingly, it would be advantageous if an organization could produce personalized display devices through a manufacturer that was willing to concede design choices, such as color and logos, to the organization. Such an arrangement would allow the organization to take advantage of the advantages of high production numbers by grouping their production with the production of other organizations. Furthermore, it would reduce the cost for all organizations involved.

Additionally, it would be advantageous if the organization were able to market the devices to fans or other followers of the organization, either through direct marketing or through the marketing efforts of the manufacturer. Marketing efforts by the manufacturer would allow the organization to produce more effective campaigns by combining the marketing budgets of many organizations.

### BRIEF SUMMARY OF SOME EXAMPLE EMBODIMENTS

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

An example embodiment includes a method of manufacturing an electronic display, where the electronic display is configured to display an image to a user. The method includes providing input circuitry, where the input circuitry receives an input signal and where the input signal is configured to be converted to an image by the electronic display. The method also includes providing display circuitry, where the display circuitry converts the input signal to the image, and receiving an emblem and color scheme from an organization. The method further includes providing a housing. The housing substantially encloses the input circuitry and display circuitry, includes the emblem received from the organization and includes the color scheme received from the organization.

Another example embodiment includes a television, where the television is configured to display an image to a user. The television includes input circuitry, where the input circuitry receives an input signal and the input signal is configured to be converted to an image for display on the television. The television also includes display circuitry, where the display circuitry converts the input signal to the image and a housing. The housing substantially encloses the input circuitry and display circuitry, includes an emblem, where the emblem is the logo of an organization and includes a color scheme of the organization. The television further includes a screen wherein the display circuitry broadcasts the image to the screen where it is displayed to a user.

Another example embodiment includes a television system, where the television system is configured to display an image to a user. The television system includes input circuitry, where the input circuitry receives an input signal and the input signal is configured to be converted to an image for display on the television system. The televisions system also includes display circuitry, where the display circuitry converts the input signal to the image and a screen, where the display circuitry broadcasts the image to the screen where it is displayed to a user. The television system further includes a housing. The housing substantially encloses the input circuitry the display circuitry, encloses the edges of the screen, includes an emblem, where the emblem is the logo of an organization and includes a color scheme of the organization. The television system further includes a memory, where the memory is configured to use the display circuitry to display the emblem when the television system is initially turned on and a remote control for the television system, where the remote control is configured to control the television system. The remote control includes a housing. The remote housing includes the emblem the color scheme of the organization.

These and other objects and features of the present invention will become more fully apparent from the following description and appended claims, or may be learned by the practice of the invention as set forth hereinafter.

### BRIEF DESCRIPTION OF THE DRAWINGS

To further clarify various aspects of some example embodiments of the present invention, a more particular description of the invention will be rendered by reference to specific embodiments thereof which are illustrated in the appended drawings. It is appreciated that these drawings depict only illustrated embodiments of the invention and are therefore not to be considered limiting of its scope. The invention will be described and explained with additional specificity and detail through the use of the accompanying drawings in which:

FIG. 1A is a front view of an electronic display;

FIG. 1B is a top view of the electronic display of FIG. 1A;

FIG. 2 illustrates an input panel for an electronic display;

FIG. 3A illustrates an example of a remote control;

FIG. 3B illustrates an example of a remote control that includes an LCD screen;

FIG. 4 illustrates an example of display circuitry; and

FIG. 5 illustrates a flow chart of a method for manufacturing an electronic display.

### DETAILED DESCRIPTION OF SOME EXAMPLE EMBODIMENTS

Reference will now be made to the figures wherein like structures will be provided with like reference designations. It is understood that the figures are diagrammatic and schematic representations of some embodiments of the invention, and are not limiting of the present invention, nor are they necessarily drawn to scale.

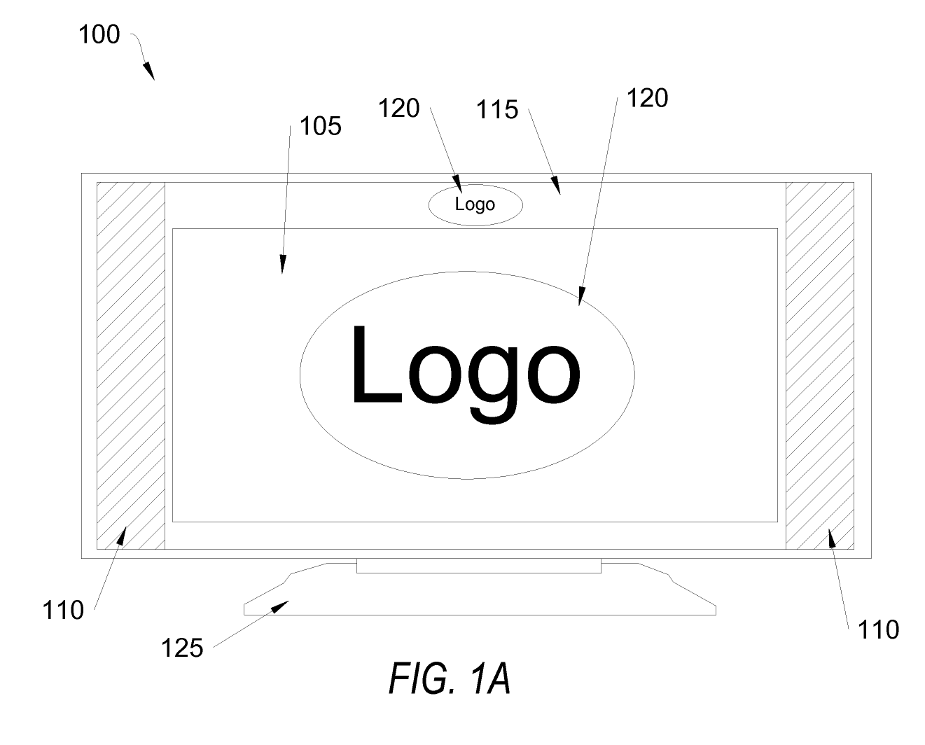

FIGS. 1A and 1B illustrate an electronic display 100 in accordance with an embodiment of the invention. FIG. 1A is a front view of the electronic display 100. FIG. 1B is a top view of the electronic display 100 of FIG. 1A. In at least one implementation, the electronic display 100 is any display device for presentation of information for visual, tactile or auditive reception, acquired, stored, or transmitted in electronic form. In particular, an electronic display 100 is a device that receives an electronic signal as input and converts the electronic signal to a sensory signal that can be received by a user. For example, an electronic display 100 can include television sets, computer monitors, video display panels, projectors, liquid crystal displays (“LCD”s), light emitting diode (“LED”) displays or speakers. One of skill in the art will appreciate that the electronic display 100 can include any other device that converts an electronic signal into a sensory signal unless otherwise stated in the specification or the claims.

In at least one implementation, the electronic display 100 can produce multiple types of sensory signals. In particular, the electronic display 100 can include circuitry able to produce an image, which can be viewed by a viewer, and circuitry able to produce sound, which can be heard by the viewer. For example, many televisions and computer monitors are manufactured with built in speakers. One of skill in the art will appreciate that the number of sensory signals produced by the electronic display 100 is not limiting unless otherwise stated in the specification or the claims.

FIGS. 1A and 1B show that the electronic display 100 includes a screen 105. In at least one implementation, the screen 105 serves as a surface for images to be shown on the electronic display 100. In particular, the electronic display 100 includes display circuitry which broadcasts an image, or series of images, that are shown on the screen 105. For example, the screen 105 can be made of glass, plastic or other material that allows the display circuitry to broadcast the image on one side of the screen 105, while a user views the image from the other side of the screen. Additionally or alternatively, the screen 105 can be a projection surface where the display circuitry 100 can broadcast an image that is reflected to a user, who is on the same side of the screen 105 as the electronic display 100. One of skill in the art will appreciate that the location of the display circuitry relative to the screen 105 and to the user is not limiting unless otherwise stated in the specification or the claims.

FIGS. 1A and 1B also show that the electronic display 100 can include one or more speakers 110. In at least one implementation, the speakers 110 can include an electroacoustic transducer that converts an electrical signal into sound that can be perceived by a user. Specifically, the speaker 110 can move in accordance with the variations of an electrical signal and causes sound waves to propagate through a medium. In particular, the speaker 110 can be used to produce sound from a data signal sent to the electronic display 100. The speaker 110 can be part of the electronic display 100 or can be an external device such as external speakers or headphones.

FIGS. 1A and 1B further show that the electronic display 100 includes a housing 115. In at least one implementation, the housing 115 substantially encloses the input circuitry and display circuitry of the electronic display 100, as discussed below. Additionally or alternatively, the housing 115 can encloses the edges of the screen 105 and the edges of the speakers 110. In particular, the edges of the screen 105 can be attached to the housing 115 so that the housing 115 can support the screen 105. Attaching the screen 105 to the housing 115 can allow the housing 115 to provide structure for the screen 105. Additionally or alternatively, attaching the screen 105 to the housing 115 can allow the screen 105 to be moved or otherwise manipulated without damaging the screen 105.

In at least one implementation, the housing 115 can be made of metal, plastic or any other material that can substantially enclose the input and display circuitry. Additionally or alternatively, the housing 115 can be made of material that is designed for aesthetic reasons. For example, the housing 115 can be made of materials, such as wood, which are designed to enhance the users experience when using the electronic display 100. One of skill in the art will appreciate that the material used to construct the housing 115 can be changed depending on the elements to be enclosed and the design preferences of the engineer.

In at least one implementation, the housing 115 can include one or more colors or color schemes. As used in the specification and the claims, the term color scheme shall refer to the use of one or more colors to create a design scheme or motif unless specified otherwise. For example, the housing 115 can include a design scheme or color scheme received from an organization, as described below. In particular, the color scheme can include the official colors of the organization. For example, if the organization is a sports team, the colors can include one or more of the sports teams colors. Additionally or alternatively the colors can be any color desired by the organization.

FIGS. 1A and 1B also show that the housing can include an emblem 120. In at least one implementation, the emblem 120 can include a logo received from the organization. For example, the emblem 120 can include a logo of a corporation, a professional sports team, a collegiate sports team, a high school sports team, an individual, a governmental entity or any other organization. One of skill in the art will appreciate that the emblem 120 can include any insignia or symbol that the organization chooses.

One of skill in the art will appreciate that the color of the housing 115 and the design and placement of the emblem 120 can allow the organization to personalize the electronic display 100. That is, the color of the housing 115 and the emblem 120 can allow the organization to produce and use an electronic display 100 which reflects the color scheme and logo of the organization.

FIGS. 1A and 1B also show that the electronic display 100 includes a stand 125. In at least one implementation, the stand 125 can be used to support the electronic display 100. In particular, the stand 125 can allow the electronic display 100 to be moved or placed in different locations as desired by the user. Additionally or alternatively, the electronic display can be mounted to a wall or otherwise supported, as desired by the user.

In at least one implementation, the stand 125 can also include the emblem 120 and can include the color scheme of the organization. In particular, the stand 125 can be designed such that the color scheme of the stand 125 matches the color scheme of the housing 115 or is complementary to the color scheme of the housing 115. For example, if the color scheme provided by the organization is green and yellow, the housing 115 and stand 125 can both include green and yellow. Additionally or alternatively, the housing 115 could be green while the stand 125 is yellow. One of skill in the art will appreciate that any combination of coloring in the housing 115 and/or the stand 125 is within the scope of the invention as described herein.

In at least one implementation, the electronic display 100 can include a memory. In particular, the memory can include instructions for the display circuitry of the electronic display 100 that overrides the initial input signal. For example, the memory can override the input signal for a specific period of time when power is initially connected to the electronic display 100 in order to display a pre-set image. For instance, the memory can override the initial input signal such that the electronic display 100 shows the emblem 120 for a period of six seconds when the electronic display 100 is initially turned on.

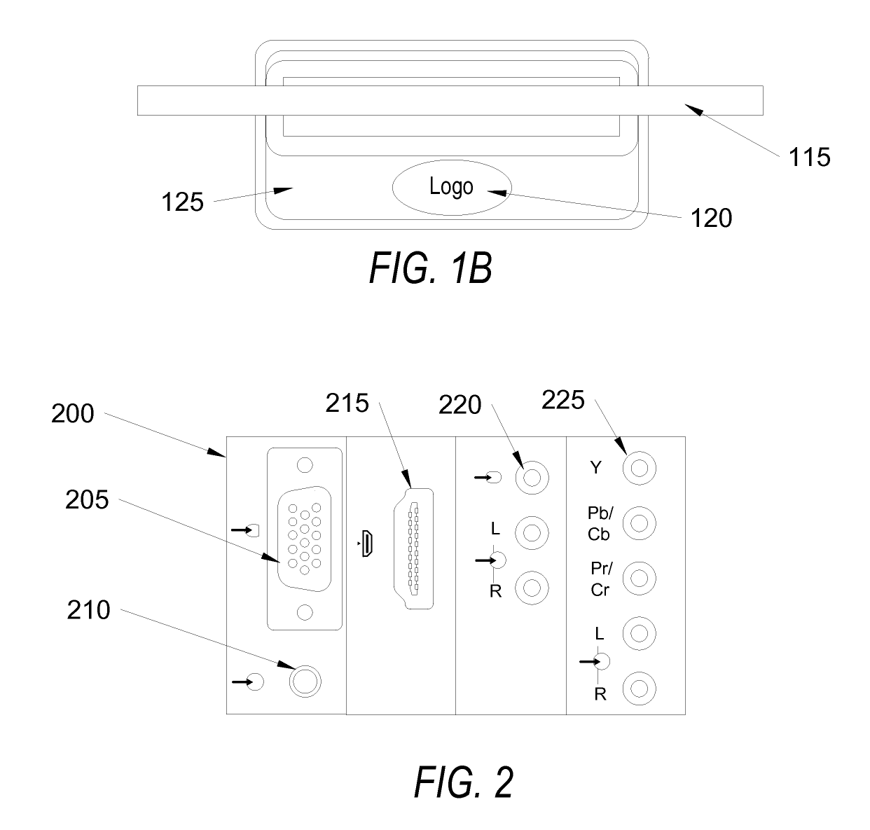

FIG. 2 illustrates an input panel 200 for an electronic display. The input panel 200 can be the input panel for the electronic display 100 of FIGS. 1A and 1B; however, one of skill in the art will appreciate that the input panel 200 can be the input panel for any electronic display. In at least one implementation, the input panel 200 can include input circuitry that can allow the electronic display to receive electronic signals that will be converted to sensory signals by the electronic display. For example, the input panel 200 can include input circuitry which allows the user to select from various inputs. In particular, the input panel 200 can allow the electronic display to select one of many possible inputs for output on the electronic display.

FIG. 2 shows that the input panel 200 can include a VGA connector 205. In at least one implementation, the VGA connector 205 can include three rows with five pins per row. In particular, the VGA connector 205 can be used to connect a computer or other device to an electronic video display. The VGA connector can include analog component RGBHV (red, green, blue, horizontal sync, vertical sync) video signals, and data.

FIG. 2 also shows that the input panel 200 can include a tip, ring, sleeve (“TRS”) connector 210 for adding an audio signal to the video signal transmitted by the VGA connector 205. In at least one implementation, the TRS connector 210 can include a stereo audio signal, where the stereo audio signal transmits a separate audio signal for left and right speakers.

FIG. 2 also shows that the input panel can include a High-Definition Multimedia Interface (“HDMI”) connector 215. In at least one implementation, an HDMI connector 215 is a compact audio/video interface for transmitting uncompressed digital data. In particular, an HDMI connector 215 can allow for the transmission of both audio and video signals to and from an electronic display. Additionally or alternatively, an HDMI connector 215 can allow a first electronic device to control a second electronic device if connected through an HDMI cable. That is, an HDMI connector 215 can include a consumer electronics connection (“CEC”) which allows one electronic device to send control signals to a connected electronic device.

FIG. 2 further shows that the input panel can include an RCA connector 220. In at least one implementation, an RCA connector 220, sometimes called a phono connector or cinch connector, is a type of electrical connector commonly used to carry audio and video signals. For example, an RCA connector 220 can include a composite video connector, a right channel audio connector and a left channel audio connector. In particular, the individual connectors of the RCA connector 220 can be color coded for ease of installation.

FIG. 2 also shows that the input panel 200 can include a YPbPr/YCbCr video connector 225. In at least one implementation, the YPbPr/YCbCr video connector 225 includes a color scheme where the video signal is converted into three components. YPbPr is an analog signal and YCbCr is a digital signal. In particular, the Y component can carry luma (brightness) and sync information, the Pb/Cb component can carry the difference between blue and luma (B-Y) and the Pr/Cr component can carry the difference between red and luma (R-Y).

One of skill in the art will appreciate that any combination of inputs in the input panel 200 is contemplated within the scope of the invention. In particular, any combination on inputs which allow an electronic display to receive input electrical signals and to convert the electrical signals to sensory signals that can be perceived by the user is contemplated unless otherwise stated in the specification or the claims.

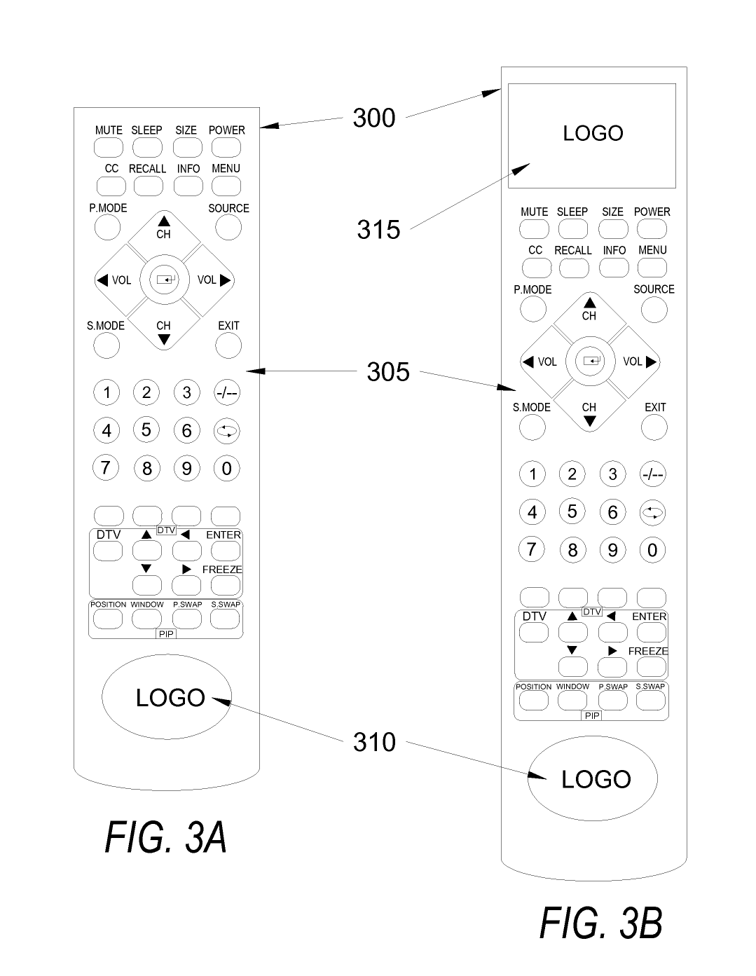

FIGS. 3A and 3B illustrate examples of a remote control 300 that can be used in combination with an electronic display. FIG. 3A illustrates an example of a remote control that includes an organization's emblem. FIG. 3B illustrates an example of a remote control that includes an LCD screen. The remote control 300 can be the remote control for the electronic display 100 of FIGS. 1A and 1B; however, one of skill in the art will appreciate that the remote control 300 can be the remote control for any electronic display.

In at least one implementation, a remote control 300 is a device used for operating the electronic display wirelessly from a short line-of-sight distance. In particular, the remote control 300 can transmit signals using electromagnetic radiation that controls various aspects of the electronic display. For example, the remote control 300 can be used to control channel, volume, input, play, pause, stop, rewind, fast-forward, select menu options and other aspects of the electronic display. Additionally or alternatively, the remote control 300 can be used to control a number of different electronic devices.

FIGS. 3A and 3B show that the remote control 300 can include a housing 305. In at least one implementation, the housing 305 can enclose or substantially enclose the circuitry of the remote control 300. In particular, the housing 305 can be made of metal, plastic or any other material that can substantially enclose the circuitry of the remote control 300. Additionally or alternatively, the housing 305 can be made of material that is designed for aesthetic reasons. For example, the housing 305 can be made of materials, such as wood, which are designed to enhance the users experience when using the remote control 300. One of skill in the art will appreciate that the material used to construct the housing 305 can be changed depending on the elements to be enclosed and the design preferences of the engineer.

In at least one implementation, the housing 305 can include one or more colors or color schemes. For example, the housing 305 can include a design scheme or color scheme received from an organization, as described below. In particular, the color scheme can include the official colors of the organization. For example, if the organization is a sports team, the colors can include one or more of the sports teams colors. Additionally or alternatively the colors can be any color desired by the organization.

FIGS. 3A and 3B also show that the housing can include an emblem 310. In at least one implementation, the emblem 310 can include a logo received from the organization. For example, the emblem 310 can include a logo of a corporation, a professional sports team, a collegiate sports team, a high school sports team, an individual, a governmental entity or any other organization. One of skill in the art will appreciate that the emblem 310 can include any insignia or symbol that the organization chooses.

One of skill in the art will appreciate that the color of the housing 305 and the design and placement of the emblem 310 can allow the organization to personalize the remote control 300. That is, the color of the housing 305 and the emblem 310 can allow the organization to produce and use an remote control 300 which reflects the color scheme and logo of the organization. For example, FIGS. 3A and 3B shows the remote control 300 with the emblem 310 placed in an area that does not contain buttons or other functional items. In contrast, the remote control 300 could include the emblem 310 as a water mark, or under the functional items of the remote control 300.

FIG. 3B further shows the remote control 300 with an LCD screen 315. In at least one implementation, the LCD screen 315 can be used to show current settings of the remote control 300, current menu options, commands for the user to select, current settings of the electronic display, the emblem 310 or any other information or options to be presented to the user.

In at least one implementation, the remote control 300 can include a memory. In particular, the memory can include instructions for the display circuitry of the remote control 300 that overrides other display signals for a certain period of time. For example, the memory can override the display signal for a specific period of time when power is initially provided to the remote control 300, or when the remote control 300 is restarted from standby mode, in order to display a pre-set image, such as the emblem 310.

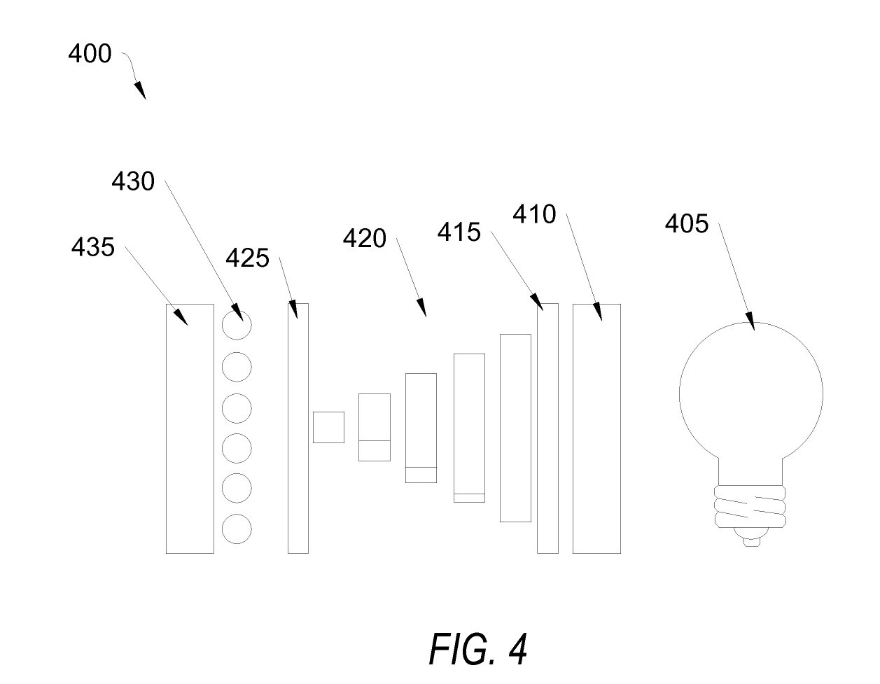

FIG. 4 illustrates an example of display circuitry 400. The display circuitry 400 can be the display circuitry for the electronic display 100 of FIGS. 1A and 1B; however, one of skill in the art will appreciate that the display circuitry 400 can be the display circuitry for any electronic display. One of skill in the art will also appreciate that the display circuitry 400 is only one example of display circuitry that can be used in an electronic display and should not be seen as limiting of the invention.

In at least one implementation, the display circuitry 400 can include an LCD. An LCD is a thin, flat electronic visual display that uses the light modulating properties of liquid crystals (“LC”s). LCs do not emit light directly and, therefore, need a light source and are classified as “passive” displays. Some types can use ambient light such as sunlight or room lighting. An LCD is an electronically-modulated optical device made up of any number of pixels filled with liquid crystals and arrayed in front of a light source (backlight) or reflector to produce images in color or monochrome.

FIG. 4 shows that the display circuitry 400 can include a light source 405. In at least one implementation, the light source 405 produces light for all of the individual pixels in the display circuitry. Additionally or alternatively, the light source 405 can produce light for a single pixel, or for a group of pixels. One of skill in the art will appreciate that any number of light sources 405 is contemplated unless otherwise stated in the specification or the claims.

FIG. 4 also shows that the display circuitry 400 can include a vertical filter 410. In at least one implementation, the vertical filter 410 prevents light that is not vertically polarized from passing through the filter. For example, the vertical filter 410 can prevent all or substantially all light that enters the filter that is either oriented at some direction other than vertical or elliptically polarized from passing through the vertical filter 410. Additionally or alternatively, the vertical filter 410 can reorient the polarization of the light to a vertical polarization.

FIG. 4 further shows that the display circuitry 400 can include a first transparent electrode 415. The light which passes through the vertical filter 410 is unimpeded as it passes through the first transparent electrode 415. In at least one implementation, the surface of the first transparent electrode 415 is aligned in a particular direction. For example, the surface for the first transparent electrode 415 can be aligned vertically, such that the electric field near the first transparent electrode 415 is aligned in a vertical direction.

FIG. 4 also shows that the display circuitry 400 can include liquid nematic crystals 420. In at least one implementation, liquid nematic crystals 420 can display properties of both liquids and solid crystals. In particular, the liquid nematic crystals 420 can rearrange themselves in the presence of an electric field, while maintaining their crystalline structure.

FIG. 4 further shows that the display circuitry can include a second transparent electrode 425. In at least one implementation, the surface of the second transparent electrode 425 can be aligned perpendicularly to the first transparent electrode 415. Such an alignment allows the liquid nematic crystals 420 near the first transparent electrode 415 to be oriented in one direction and the liquid nematic crystals 420 near the second transparent electrode 425 to be aligned perpendicular to the liquid nematic crystals 420 near the first transparent electrode 415. The liquid nematic crystals 420 in between the first transparent electrode 415 and the second transparent electrode 425 can align themselves helically between the two orientations. One of skill in the art will appreciate that higher the voltage between the first transparent electrode 415 and the second transparent electrode 425, the more helical the alignment of the liquid nematic crystals 420. As the alignment of the liquid nematic crystals 420 become more helical, a higher proportion of the light passing through the liquid nematic crystals 420 becomes polarized in a different direction. The voltage between the first transparent electrode 415 and the second transparent electrode 425 determines that amount of light that is reoriented from a vertical polarization to a horizontal polarization. Thus, if the voltage is sufficient, substantially all of the light which passed through the first transparent electrode 415 with a vertical polarization passes through the second transparent electrode 425 with a horizontal polarization.

FIG. 4 also shows that the display circuitry can include a horizontal filter 430. In at least one implementation, the horizontal filter 430 blocks light that is not horizontally polarized. In particular, light that passed through the vertical filter 410 and was reoriented by the liquid nematic crystals 420 to a horizontal polarization can pass through the horizontal filter 430. In contrast, light that passed through the vertical filter 410 but that was not reoriented by the liquid nematic crystals 420 to a horizontal polarization can be blocked by the horizontal filter 430.

FIG. 4 further shows that the display circuitry can include a color filter 435. In at least one implementation, the color filter 435 can change the color of the light from the light source 405 to a different color. In particular, if the light source 405 produces white light, the color filter 435 can block any components of the white light that do not correspond to the color of the color filter 435.

In at least one implementation, the display circuitry 400 can include multiple cells, each of which contains a different color filter 435. For example, each individual pixel of an LCD display device can be divided into three subpixels, which are colored red, green, and blue, respectively, through the use of three color filters 435. The intensity of each subpixel can be controlled independently, through variations of the voltage between the first transparent electrode 415 and the second transparent electrode 425 to yield thousands or millions of possible colors for each pixel.

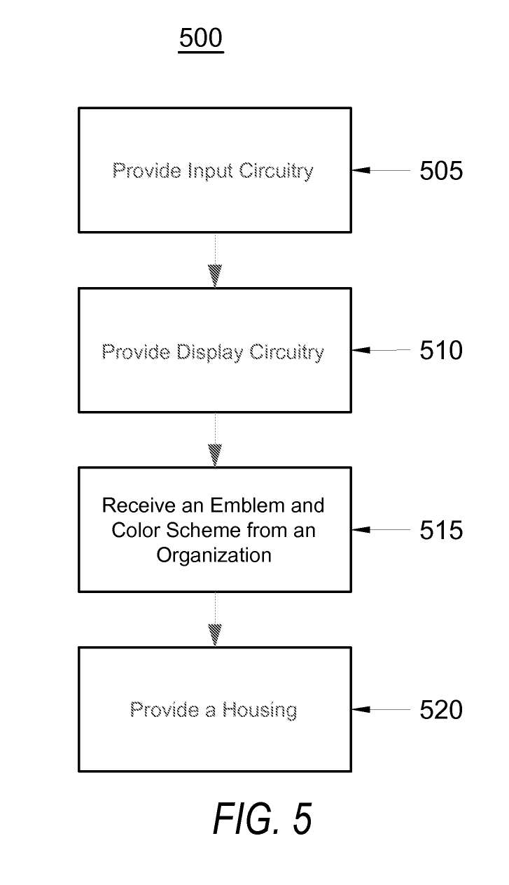

FIG. 5 illustrates a flow chart of a method 500 for manufacturing an electronic display. In at least one implementation, the method 500 can be used to manufacture the electronic display 100 of FIGS. 1A and 1B; however, one of skill in the art will appreciate that the method 500 can be used to manufacture any electronic display. One of skill in the art will also appreciate that the method 500 is only one example of a method that can be used to manufacture an electronic display and should not be seen as limiting of the invention.

FIG. 5 shows that the method 500 can include providing 505 input circuitry. In at least one implementation, the input circuitry is configured to receive an input signal where the input signal is configured to be converted to an image by the electronic display. In particular, the input circuitry could receive multiple input signals in parallel with one another. The input circuitry can allow the user to select one or more of the input signals to be output as a sensory signal by the electronic display.

FIG. 5 also shows that the method 500 includes providing 510 display circuitry. In at least one implementation, the display circuitry converts the input signal to the image to be displayed. For example, the display circuitry can include data to be displayed on individual pixels or subpixels and the input signal can include the information to be displayed on each pixel or subpixel. Additionally or alternatively, the input signal can include data to be displayed on individual pixels and the display circuitry can obtain the correct subpixel settings from the pixel data.

FIG. 5 further shows that the method 500 includes receiving 515 an emblem and color scheme from an organization. In particular, the color scheme can include the official colors of the organization. For example, if the organization is a sports team, the colors can include one or more of the sports teams colors. Additionally or alternatively the colors can be any color desired by the organization. In at least one implementation, the color scheme can include colors identified by one or more Pantone Matching System color codes from the organization.

In at least one implementation, the emblem 120 can include a logo received from the organization. For example, the emblem 120 can include a logo of a corporation, a professional sports team, a collegiate sports team, a high school sports team, an individual, a governmental entity or any other organization. One of skill in the art will appreciate that the emblem 120 can include any insignia or symbol that the organization chooses.

FIG. 5 also shows that the method 500 includes providing 520 a housing. In at least one implementation, the housing substantially encloses the input circuitry and display circuitry. As used herein, the phrase “substantially encloses the input circuitry and display circuitry” means that the input circuitry and display circuitry are enclosed unless such enclosure would impair the function of the input circuitry and display circuitry and unless otherwise enclosed by other components, such as a screen. For example, the input circuitry can include one or more connectors which extend through the housing for the purpose of connecting an external device to the electronic display.

In at least one implementation, the housing also includes the emblem received from the organization and the color scheme received from the organization. For example, the housing can include the emblem on the front of the housing near the top center. Additionally or alternatively, the housing can include one or more colors as provided in the color scheme.

In at least one implementation, the method 500 can also include providing a screen. In particular, the display circuitry can broadcast the image on the screen so that the image can be viewed by a user. The housing can enclose the edges of the screen. In particular, the edges of the screen can be attached to the housing so that the housing can support the screen. Attaching the screen to the housing can allow the housing to provide structure for the screen. Additionally or alternatively, attaching the screen to the housing can allow the screen to be moved or otherwise manipulated without damaging the screen.

In at least one implementation, the method 500 can further include providing a remote control for the electronic display. In particular, the remote control can include a remote control housing. The remote control housing can include the emblem received from the organization and the color scheme received from the organization. In particular, the remote control can be designed such that the color scheme of the remote control matches the color scheme of the display housing or is complementary to the color scheme of the display housing. For example, if the color scheme provided by the organization is green and yellow, the display housing and remote control can both include green and yellow. Additionally or alternatively, the display housing could be green while the remote control is yellow. One of skill in the art will appreciate that any combination of coloring in the display housing and/or the remote control is within the scope of the invention as described herein.

In at least one implementation, the method 500 can also include providing a memory. In particular, the memory can be configured to use the display circuitry to display the emblem when the electronic display is initially turned on. For example, the memory can override the input signal for a specific period of time when power is initially connected to the electronic display in order to display a pre-set image. For instance, the memory can override the initial input signal such that the electronic display shows the emblem for six seconds when the electronic display is initially turned on.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method of manufacturing an electronic display, wherein the electronic display is configured to display an image to a user, the method comprising:
providing input circuitry, wherein the input circuitry receives an input signal and wherein the input signal is configured to be converted to an image by the electronic display;
providing display circuitry, wherein the display circuitry converts the input signal to the image;
receiving an emblem and color scheme from an organization; and
providing a housing, wherein the housing:
substantially encloses the input circuitry and display circuitry;
includes the emblem received from the organization; and
includes the color scheme received from the organization.

2. A method according to claim 1, wherein the method further comprises:
providing a screen, wherein the display circuitry broadcasts the image onto the screen.

3. A method according to claim 1, wherein the organization includes a sports team.

4. A method according to claim 3, wherein the sports team includes a professional sports team.

5. A method according to claim 1, wherein the organization includes a college or university.

6. A method according to claim 1, wherein the organization includes an individual.

7. A method according to claim 1, wherein the organization includes a corporation.

8. A method according to claim 1, wherein the method further comprises:
providing a remote control for the electronic display, wherein the remote control includes a remote control housing and wherein the remote control housing includes:
the emblem; and
the color scheme of the organization.

9. A method according to claim 1, wherein the method further comprises:
providing a memory, wherein the memory is configured to use the display circuitry to display the emblem when the electronic display is initially turned on.

10. A method according to claim 1, wherein receiving the color scheme from the organization includes receiving one or more colors from the organization to be used in coloring the housing.

11. A method according to claim 10, wherein the receiving the color scheme from the organization includes receiving one or more Pantone Matching System color codes from the organization.

12. A television, wherein the television is configured to display an image to a user, the televisions comprising:
input circuitry, wherein the input circuitry receives an input signal and wherein the input signal is configured to be converted to an image for display on the television;
display circuitry, wherein the display circuitry converts the input signal to the image;
a housing, wherein the housing:
substantially encloses the input circuitry and display circuitry;
includes an emblem, wherein the emblem is the logo of an organization; and
includes a color scheme of the organization; and
a screen, wherein the display circuitry broadcasts the image to the screen to be displayed to a user.

13. A television according to claim 12, wherein the television further includes a memory, wherein the memory is configured to use the display circuitry to display the emblem when the television is initially turned on.

14. A television according to claim 12, wherein the television further includes:
a remote control for the television, wherein the remote control is configured to control the television and wherein the remote control includes a remote control housing, wherein the remote control housing includes:
the emblem; and
the color scheme of the organization.

15. A television according to claim 12, wherein the television further includes:
a remote control for the television, wherein the remote control is configured to control the television and wherein the remote control includes:
an electronic display, wherein the electronic display is configured to display menu options to a user.

16. A television according to claim 15, wherein the remote control further includes:
a memory, wherein the memory is configured to:
display the emblem when the remote control is initially turned on; or
display the emblem when the remote control is awakened from a standby mode.

17. A television according to claim 15, wherein the remote control includes
a remote control housing and wherein the remote control housing includes:
the emblem; and
the color scheme of the organization.

18. A television system, wherein the television system is configured to display an image to a user, the television system comprising:
input circuitry, wherein the input circuitry receives an input signal and wherein the input signal is configured to be converted to an image for display on the television system;
display circuitry, wherein the display circuitry converts the input signal to the image;
a screen, wherein the display circuitry broadcasts the image to the screen where it is displayed to a user;
a housing, wherein the housing:
substantially encloses the input circuitry the display circuitry;
encloses the edges of the screen;
includes an emblem, wherein the emblem is the logo of an organization; and
includes a color scheme of the organization;
a memory, wherein the memory is configured to use the display circuitry to display the emblem when the television system is initially turned on; and
a remote control for the television system, wherein the remote control is configured to control the television system and wherein the remote control includes a remote control housing and the remote control housing includes:
the emblem; and
the color scheme of the organization.

19. A television system according to claim 18, wherein the remote control further includes:
an electronic display, wherein the electronic display is configured to display menu options to a user.

20. A television system according to claim 18, wherein the remote further includes:
a remote control memory, wherein the remote control memory is configured to:
display the emblem when the remote control is initially turned on; or
display the emblem when the remote control is awakened from a standby mode.
